(19) United States
(12) Patent Application Publication
(10) Pub. No.: US 2009/0117672 A1
(43) Pub. Date: May 7, 2009

(54) Light emitting devices with phosphor wavelength conversion and methods of fabrication thereof

(75) Inventors: James Caruso, Albuquerque, NM (US); Charles O. Edwards, Rio Rancho, NM (US)

Correspondence Address: FLIESLER MEYER LLP, 650 CALIFORNIA STREET, 14TH FLOOR, SAN FRANCISCO, CA, 94108, US

(73) Assignee: Intematix Corporation, Fremont, CA (US)

(21) Appl. No.: 11/906,545

(22) Filed: Oct. 1, 2007

(51) Int. Cl. H01L 21/66; B05C 9/10

(52) U.S. Cl. 438/7; 438/35; 118/708; 257/E21.521

(57) ABSTRACT

A method of fabricating a light emitting device having a specific target color, CIE xy, of emitted light is described. The device comprises a light emitting diode that is operable to emit light of a first wavelength range and at least one phosphor material which converts at least a part of the light into light of a second wavelength range wherein light emitted by the device comprises the combined light of the first and second wavelength ranges. The method comprises: depositing a pre-selected quantity of the at least one phosphor material on a light emitting surface of the light emitting diode; operating the light emitting diode; measuring the color of light emitted by the device; comparing the measured color with the specific target color; and depositing and/or removing phosphor material to attain the desired target color.

### BACKGROUND OF THE INVENTION

1. Field of the Invention

The invention relates to methods and apparatus for fabricating a light emitting device with phosphor wavelength conversion. More particularly the invention concerns light emitting devices of a type comprising a light emitting diode (LED) operable to emit light of a first wavelength range and a phosphor material that converts at least a part of the light into light of a second wavelength range.

2. Description of the Related Art

White light emitting diodes (LEDs) are known in the art and are a relatively recent innovation. It was not until LEDs emitting in the blue/ultraviolet part of the electromagnetic spectrum were developed that it became practical to develop white light sources based on LEDs. As taught for example in U.S. Pat. No. 5,998,925, white light generating LEDs (“white LEDs”) include one or more phosphor materials, that is photo-luminescent materials, which absorb a portion of the radiation emitted by the LED and re-emits radiation of a different color (wavelength). Typically, the LED chip or die generates blue light and the phosphor(s) absorbs a percentage of the blue light and re-emits yellow light or a combination of green and red light, green and yellow light or yellow and red light. The portion of the blue light generated by the LED that is not absorbed by the phosphor is combined with the light emitted by the phosphor provides light which appears to the human eye as being nearly white in color.

As is known, the correlated color temperature (CCT) of a white light source is determined by comparing its hue with a theoretical, heated black-body radiator. CCT is specified in Kelvin (K) and corresponds to the temperature of the black-body radiator which radiates the same hue of white light as the light source. The CCT of a white LED is generally determined by the phosphor composition and the quantity of phosphor incorporated in the LED.

White LEDs are often fabricated by mounting the LED chip in a metallic or ceramic cup (housing) using an adhesive and then bonding lead wires to the chip. To increase the efficiency of the device, the cup will often have a reflecting inner surface to reflect light out of the device. The phosphor material, which is in powder form, is typically mixed with a silicone binder and the phosphor mixture is then placed on top of the LED chip. A problem in fabricating white LEDs is variation of CCT and color hue between LEDs that are supposed to be nominally the same. This problem is compounded by the fact that the human eye is extremely sensitive to subtle changes in color hue especially in the white color range.

To alleviate the problem of color variation in LEDs with phosphor wavelength conversion as is described above, in particular white LEDs, LEDs are categorized post-production using a system of “bin out” or “binning.” In binning, each LED is operated and the actual color of its emitted light measured. The LED is then categorized or binned according to the actual color of light the device generates not based on the target CCT with which it was produced. FIG. 1 is a CIE (Commission Internationale de l'Eclairage) 1931 chromaticity diagram for a cold white (CW) LED indicating four regions of the color space or color bins. More typically nine or more bins are used to categorize white LEDs. A disadvantage of binning is increased production costs and a low yield rate as often only two out of the nine bins are acceptable for an intended application resulting in supply chain challenges for white LED suppliers and customers.

U.S. Pat. No. 6,623,142 teaches adjusting the spectral characteristics of an LED by placing a filter in the LEDs light emission path. The filter has a filter pattern that changes at least one color and intensity of light and which is generated based on a shift value corresponding to a deviation between at least one of the color and intensity of the emitted light from a reference. The filter can be printed using ink jet printing or other printing methods on the lens of the LED or printed on a cap that is later attached to the LED. The specific ink colors selected for the filter depend on the deviation of each LED's emitted light from a specified tolerance. The filters are stated as creating a high degree of color and intensity uniformity without requiring labor and cost-intensive binning. A disadvantage of filtering is that it is based on absorption to remove spectral components from the emitted spectrum and as a result reduces efficiency of the LED. Moreover, filtering cannot be used to correct spectral emission when a spectral component is absent, in other words, this approach is unable to “add” spectral wavelengths to the white LED emission.

The variation in color hue of emitted light of LEDs with traditional phosphor wavelength conversion is believed to result from variations in the volume, composition and position of the phosphor material on the LED chip. The inventors have appreciated however that the variation in color hue can additionally depend on factors including:
variations in bonding wire shape and location which can affect wetting of the phosphor
adhesive bleed out which can affect the wetting of the phosphor
variations in emission direction of the LED chip
variations in the reflector characteristic
variations or aging in the phosphor/silicone blend
wavelength emission distribution of LED chips.

It is believed that all of these factors can affect the color hue of light generated by a light emitting device that includes phosphor wavelength conversion.

### SUMMARY OF THE INVENTION

The present invention arose in an endeavor to, at least in part, address the problem of color hue and/or CCT variation of LEDs that include phosphor wavelength conversion and to reduce or even eliminate the need for binning.

Embodiments of the invention are directed to depositing a pre-selected quantity of one or more phosphor materials on a light emitting surface of the light emitting diode; operating the light emitting diode, measuring the color of light emitted by the device; and depositing (adding) and/or removing (subtracting) phosphor material to attain a desired target color (target CIE xy).

According to the invention there is provided a method of fabricating a light emitting device having a specific target color (CIE xy) of emitted light, the device comprising at least one light emitting diode (LED) operable to emit light of a first wavelength range and at least one phosphor material which converts at least a part of the light into light of a second wavelength range wherein light emitted by the device comprises the combined light of the first and second wavelength ranges, the method comprising:
a) depositing a pre-selected quantity of the at least one phosphor material on a light emitting surface of the at least one LED;
b) operating the at least one LED;
c) measuring the color of light emitted by the device;
d) comparing the measured color with the specific target color; and
e) in dependence on the comparison depositing and/or removing a quantity of phosphor material substantially to attain the specific target color.

To ensure that further phosphor material has to be deposited to attain the specific target color (CIE xy), the method can further comprise selecting the pre-selected quantity to ensure that the proportion of light of the second wavelength range is lower than is required in the specific target color. Alternatively, the method can comprise selecting the pre-selected quantity to ensure that the proportion of light of the second wavelength range is greater than in the specific target color. This arrangement ensures that phosphor material will have to be removed to attain the specific target color

Preferably, the quantity of phosphor material to be deposited and/or removed is selected using a look-up table.

The method can further comprise operating the at least one light emitting diode a further time and measuring the color of light emitted by the device to verify that the color of light emitted by the device corresponds to substantially the specific target color. Preferably, when the color is measured a further time this information is used to update the look-up table. The method steps b) to e) can be repeated as many times as is required to attain the specific target color or to attain a color that is within pre-defined limits (that is a range of CIE xy coordinates).

The phosphor material can be removed by ablating, slicing, milling, abrading, drilling, routing, buffing or grinding. Alternatively, phosphor can be removed by wiping before the binder material sets.

To increase the intensity of light emitted by the device, the device can comprise a plurality, typically an array, of light emitting diodes each of which includes the at least one phosphor material. When fabricating such a device the method comprises:
a) depositing a pre-selected quantity of the at least one phosphor material on a light emitting surface of each of the LEDs;
b) operating all of the LEDs;
c) measuring the color of light emitted by the device;
d) comparing the measured color with the specific target color; and
e) in dependence on the comparison depositing on, and/or removing from, a selected number of the light emitting diodes, a fixed (unit) quantity of phosphor material, the number being selected to substantially to attain the specific target color. A particular advantage of such a method is that only fixed quantities of phosphor need be deposited and/or removed which can simplify the method.

The invention is particularly suited to the fabrication of white light emitting devices of a specific correlated color temperature (CCT). Often such devices include two or more different phosphor materials that each emit light of different wavelength ranges. According to a further aspect of the invention there is provided a method of fabricating a light emitting device having a specific target color (CIE xy) of emitted light, the device comprising a light emitting diode operable to emit light of a first wavelength range and at least first and second phosphor materials which respectively convert at least a part of the light into light of second and third wavelength ranges wherein light emitted by the device comprises the combined light of the first, second and third wavelength ranges, the method comprising:
a) depositing pre-selected quantities of the first and second phosphor materials on a light emitting surface of the light emitting diode;
b) operating the light emitting diode;
c) measuring the color of light emitted by the device;
d) comparing the measured color with the specific target color; and
e) in dependence on the comparison depositing and/or removing selected quantities of the first and second phosphor materials substantially to attain the specific target color.

As in the method according to a first embodiment of the invention the method can further comprise selecting the pre-selected quantities of phosphor materials to ensure that the proportion of light of the second and third wavelength ranges are lower than in the specific target color. Alternatively, the method can further comprise selecting the pre-selected quantities of phosphor materials to ensure that the proportion of light of the second and third wavelength ranges are greater than in the specific target color. Preferably, the quantities of phosphor materials to be deposited and/or removed is selected using a look-up table. When the light emitting device comprises a plurality of light emitting diodes including at least first and second phosphor materials, the method comprises in dependence on the comparison depositing on, and/or removing from, a selected number of the light emitting diodes fixed quantities of the phosphor materials, the number being selected to substantially to attain the specific target color.

According to a yet further aspect of the invention there is provided an apparatus for fabricating a light emitting device having a specific target color of emitted light, the device comprising a light emitting diode operable to emit light of a first wavelength range and at least one phosphor material which converts at least a part of the light into light of a second wavelength range wherein light emitted by the device comprises the combined light of the first and second wavelength ranges, the apparatus comprising:
a dispenser for depositing a pre-selected quantity of the at least one phosphor material on a light emitting surface of the light emitting diode;
a controller operable to operate the light emitting diode; and
light measuring means for measuring the color of light emitted by the device; wherein the controller is operable to compare the measured color with the specific target color and in dependence on the comparison to deposit a further selected quantity of phosphor material substantially to attain the specific target color.

In an alternative embodiment, an apparatus for fabricating a light emitting device having a specific target color of emitted light comprises:
a dispenser operable to deposit a pre-selected quantity of the at least one phosphor material on a light emitting surface of the light emitting diode;
a controller operable to operate the light emitting diode;
light measuring means for measuring the color of light emitted by the device; and
phosphor removing means operable to remove a quantity of phosphor material to attain the specific target color, wherein the controller is operable to compare the measured color with the specific target color and in dependence on the comparison to select the quantity of phosphor material to be removed substantially to attain the specific target color.

Advantageously, the apparatus can further comprises a look-up table for selecting the quantity of further phosphor material to be deposited and/or removed.

In one arrangement the dispenser comprises a plunger type dispenser head that is capable of dispensing nano-liter volumes of phosphor material.

Advantageously, the phosphor removing means comprises a laser operable to ablate the selected quantity of phosphor material.

When the light emitting device comprises a plurality of light emitting diodes including at least one phosphor material, the controller can be operable in dependence on the comparison to deposit on a selected number the light emitting diodes a fixed quantity of the phosphor material, the number being selected to substantially to attain the specific target color. Alternatively, the controller is operable in dependence on the comparison to remove from a selected number the light emitting diodes a fixed quantity of the phosphor material, the number being selected to substantially to attain the specific target color.

The invention is particularly suited to the fabrication of light emitting devices that include two phosphor materials such as white light emitting devices. In accordance with a yet further aspect of the invention there is provided an apparatus for fabricating a light emitting device having a specific target color of emitted light, the device comprising at least one light emitting diode operable to emit light of a first wavelength range and first and second phosphor materials which respectively convert at least a part of the light into light of second and third wavelength ranges wherein light emitted by the device comprises the combined light of the first, second and third wavelength ranges, the apparatus comprising:
a first dispenser for depositing a pre-selected quantity of a mixture of the first and second phosphor materials on a light emitting surface of the at least one light emitting diode;
a second dispenser for depositing the first phosphor material;
a third dispenser for depositing the second;
a controller operable to operate the at least one light emitting diode;
light measuring means for measuring the color of light emitted by the device; wherein the controller is operable to compare the measured color with the specific target color and in dependence on the comparison to deposit using the second and third dispensers selected quantities of the first and second phosphor materials substantially to attain the specific target color.

### BRIEF DESCRIPTION OF THE DRAWINGS

In order that the present invention is better understood embodiments of the invention will now be described, by way of example only, with reference to the accompanying drawings in which:

FIG. 1 is a CIE xy 1931 chromaticity diagram illustrating “bin out” for a cold white (CW) light emitting diode as previously described;

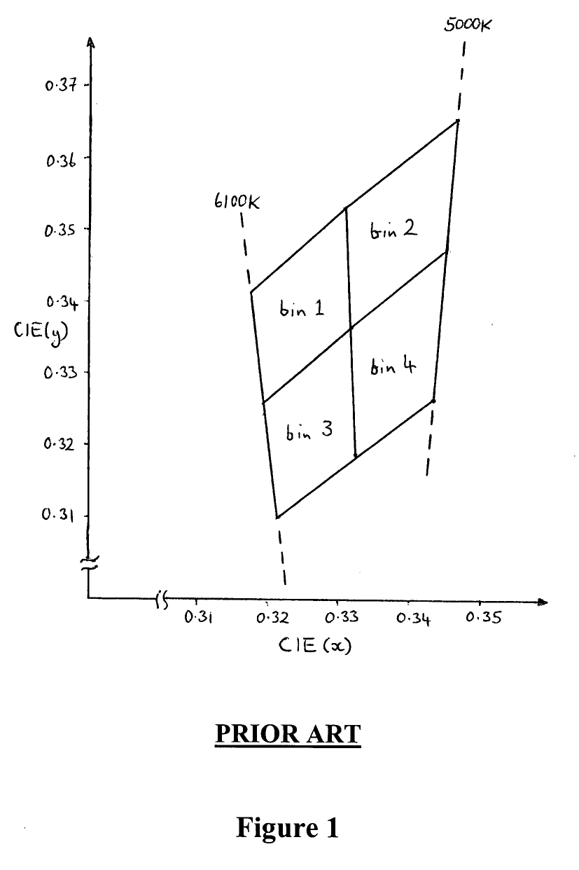

FIGS. 2(a) to (f) are schematic representations of the method steps of the invention for fabricating a white light emitting device including phosphor wavelength conversion;

FIG. 3 is a CIE xy 1931 chromaticity diagram illustrating the method of color correction of the method of FIG. 2;

FIGS. 4(a) to (f) are schematic representations of the method steps in accordance with a further embodiment of the invention for fabricating a color light emitting device including phosphor wavelength conversion; and

FIG. 5 is a CIE xy chromaticity diagram illustrating the method of color correction of the method of FIG. 4.

### DETAILED DESCRIPTION OF THE INVENTION

Method 1

A method in accordance with a first embodiment of the invention will be described in relation to the fabrication of a white light emitting device of a specific color temperature and hue. In the this patent specification color is defined in terms of chromaticity values such that a specific color is defined as having specific CIE xy chromaticity coordinates. It will be appreciated however, that other systems of defining color can be used with the method of the invention.

The white light device 10 comprises an LED chip 20 such as an InGaN/GaN (indium gallium nitride/gallium nitride) based LED chip that generates excitation radiation (light) of a first wavelength range, typically blue light of wavelength 400 to 465 nm. The device 10 further includes two different light emitting phosphor (photo-luminescent or wavelength conversion) materials that respectively convert at least a part of the light emitted by the chip into light of different colors such as for example yellow and green light. The blue light emitted by the chip combined with the yellow and green light emitted by the phosphors gives emitted light that appears white in color and is of the specific color temperature and/or hue. Although the LED chip 20 will in practice be mounted in a ceramic or metallic cup such packaging is not depicted in the accompanying figures.

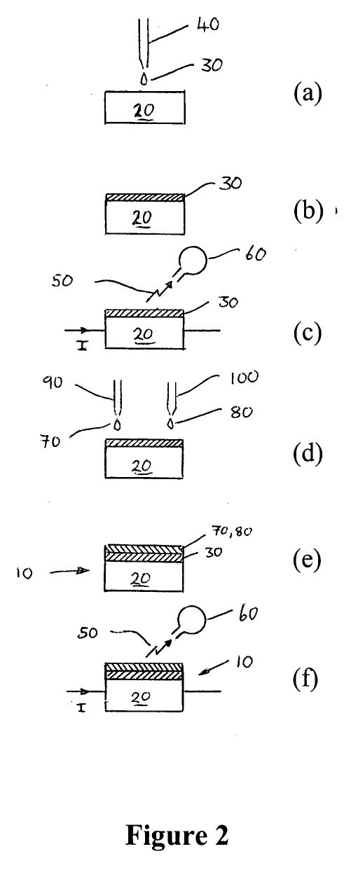

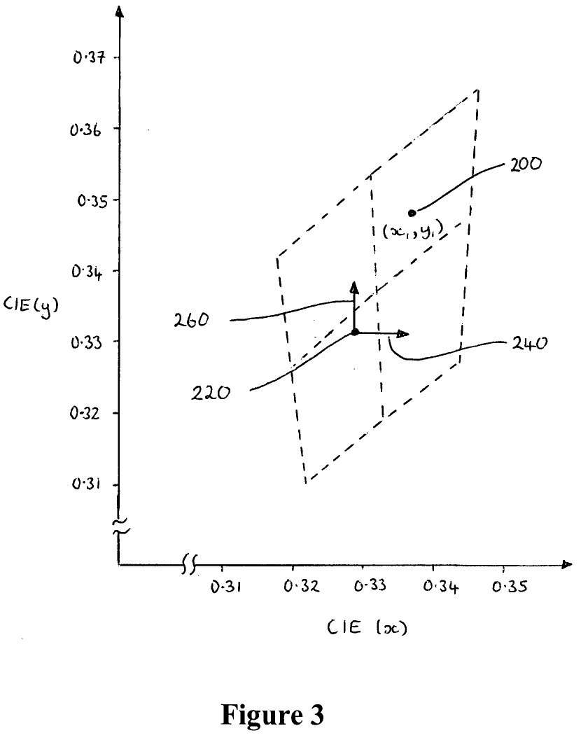

Referring to FIGS. 2(a) to (f) there are shown the method steps of the invention for fabricating a white light emitting device 10 of a specific color temperature (color hue). The specific color hue, hereinafter termed the target color, is indicated as point 200 on the CIE chromaticity diagram of FIG. 3 and has chromaticity coordinates CIE (x₁, y₁). The method of the invention is preferably implemented in the form of a fully automated production line.

Step 1—FIGS. 2(a) and (b): The phosphor materials, which are in powder form, are mixed in pre-selected proportions with a transparent binder (bonding) material such as for example a fast-drying thermosetting transparent silicone. An example of a suitable silicone material is GE's silicone RTV615. The weight ratio loading of phosphor mixture to silicone is in a range 5 to 50% depending on the required target color of the device. In a first step, a pre-selected quantity of the yellow and green light emitting phosphor mixture 30 is deposited on the light emitting surface of the LED chip 20. The phosphor binder mixture can be deposited using a dispenser 40 such as nano-liter size plunger type dispenser head made by Asymtek. The pre-selected quantity (volume) of phosphor mixture is selected to ensure that the proportion of yellow and green light is lower than in the target color, CIE (x₁, y₁). It will be appreciated that a reduction in the proportion of the green light contribution will generally result in CIE (y) being lower and a reduction in the proportion of the yellow light contribution will generally result in a reduction in CIE (x).

Step 2—FIG. 2(c): The LED chip 20 is powered up and the color of light 50 emitted by the device 20 measured using a photo-meter (calorimeter or spectrometer) 60. The color is preferably measured in terms of chromaticity coordinates CIE x,y. The measured color hue, indicated as point 220 on the chromaticity diagram of FIG. 3, is compared with the target color 200 CIE (x₁, y₁) and the quantity of additional yellow and green phosphor materials needed to attain the target color calculated. FIG. 3 shows how the addition of further yellow phosphor material will move the color in a direction substantially corresponding to arrow 240 and the addition of green phosphor will shift the color in a direction substantially corresponding to the arrow 260. (It will be appreciated that the addition of yellow phosphor will also move the color in the direction of the arrow 260 to a much lesser extent and likewise the addition of green phosphor will move the color in the direction of arrow 240 to a lesser extent.) The use of two different phosphor materials whose quantities can be independently controlled enables substantially independent control of the color in x and y directions of the chromaticity diagram. In a preferred apparatus, a look-up table (commonly referred to as LUT and used herein) is used to determine the quantity of additional phosphor materials to be deposited. The LUT can include the following parameters: target CIE (x₁, y₁), actual CIE (x,y), quantity of additional yellow phosphor, and quantity of additional green phosphor. The look-up table can be derived by initially fabricating a library of devices with differing amounts of phosphor and measuring the color of emitted light. The LUT is preferably based on a uniform color space such as for example CIE 1976 (L*a*b*) color space (CIELAB) in which the color values are perceptually linear in that a change of the same amount in a color value produces a change of about the same visual importance.

Step 3—FIGS. 2(d) and (e): The selected quantities of yellow 70 and green 80 phosphor materials calculated to attain the target color are deposited on the LED chip 20. The phosphor material can be deposited using a respective dispenser 90, 100 to deposit the selected volumes of each material. The phosphor dispensers 40, 90 and 100 preferably comprise a respective nano-liter size plunger type dispenser head of a multi-head dispenser in which is each head is capable of dispensing phosphor material at a same location. Since the actual color of emission of the device will already be close to the target color only a small additional quantity of phosphor needs to be deposited and it is preferred to use phosphor mixtures with a lower percentage loading of phosphor to attain a more accurate control over the quantity of deposited phosphor.

Step 4—FIG. 2(f): Optionally, the LED chip 20 is powered up a second time and color of light emitted by the device 10 measured to verify that the device is emitting the target color CIE (x₁, y₁) of light. Although it is unnecessary to measure the color of light emitted by the device a second time it can provide a method of quality control checking. Additionally, the measured color can be used to update the look-up table and to refine the system.

Since there can be a variation in the spectral emission of LED chips, the method can further comprise initially powering up the LED chip 20, measuring the color of its light emission using the photo-meter 60 and based on the measured color selecting the pre-selected quantity of phosphor mixture 30 to be deposited in step 1.

The method has been described in relation to fabricating a single light emitting device and it will be appreciated that the method is particularly suited to, and intended for, high volume fabrication of light emitting devices. In one method batches of light emitting devices can be fabricated by processing a number of LED chips at a time. Firstly, the pre-selected quantity of phosphor mixture is deposited on each chip. Each LED chip is then powered up and the color of light emitted by the device measured. For each device the quantities of additional phosphor required to achieve the target color of emitted light is calculated. Finally, the selected quantities of phosphor materials are deposited on each device. A production line can be implemented in the form of an automated conveyor in which batches of LED chips pass between various stations.

So far the method of fabricating a light emitting device that comprises a single LED chip with phosphor wavelength conversion has been described. Often, however, high intensity LED based light emitting devices, such as those intended for lighting applications, comprise a plurality or array of LED chips. The method of the invention can be readily applied to the fabrication of such devices.

The fabrication of a white light emitting device comprising a four by four array of sixteen LED chips is now described though the method can be applied to other LED arrays such as a linear array with a differing number of LED chips. The pre-selected quantities of yellow and green light emitting phosphor materials are deposited on each LED chip of the array. Again the pre-selected quantities of phosphor materials initially deposited is selected such that the proportion of yellow and green light is deliberately lower than is required to attain the target color CIE (x₁, y₁). The color of light emitted by each LED chip of the array can be optimized to the target color using steps 2 and 3 described above. In an alternative method however, the net color of light emitted by the device is optimized to the target color. In the latter all LED chips of the array are powered up and the net color of light emitted by all of LEDs of the array is measured. The measured color is compared with the target color and the quantities of yellow and green phosphor materials that need to be deposited to attain the target color calculated. In a first arrangement the selected quantity of phosphor materials is deposited on each LED chip of the array in the manner of step 4. A disadvantage of this method is that varying quantities of phosphor material will need to be deposited to attain the target color for different devices. In an alternative method only set unit quantities (volumes) of phosphor are deposited onto one or more LED chips of the arrays. For an array comprising sixteen LED chips and two phosphor materials there are a possible 256 (16×16) color corrections for a given unit volume of phosphor.

Method 2

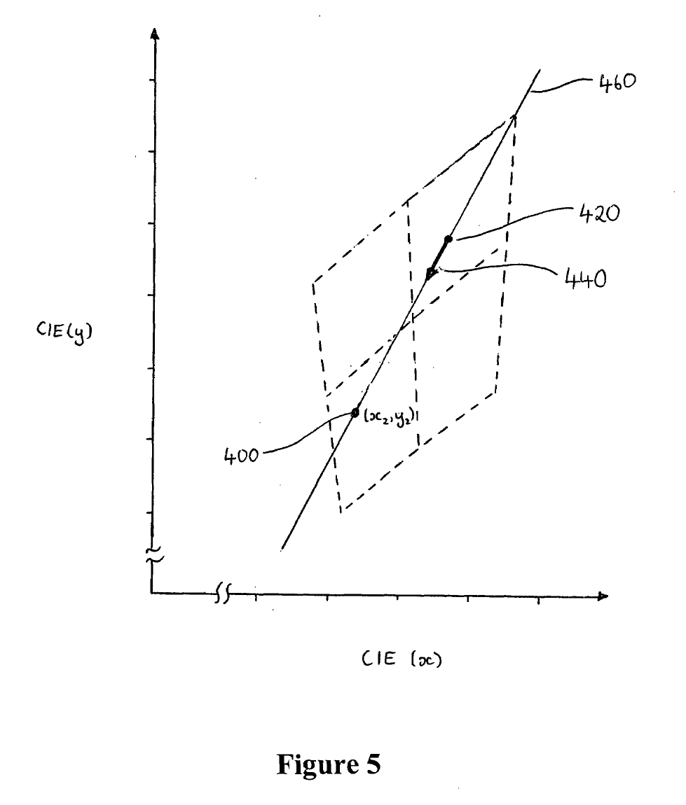

In a second method an excess of phosphor material is deliberately deposited and phosphor material then removed to attain the target color. This method is more suited to light emitting devices that include only a single phosphor material. The method of the invention will be described in relation to the fabrication of color light emitting device of a specific target color hue. The color light emitting device 310 comprises an LED chip 320 such as for example an InGaN/GaN (indium gallium nitride/gallium nitride) based LED chip that generates excitation radiation of a first wavelength range for example blue light of wavelength 400 to 450 nm. The device further includes a light emitting phosphor (photo luminescent or wavelength conversion) material that converts at least a part of the light emitted by the chip into light of a different color such as for example green light. The blue light emitted by the chip combined with the green light emitted by the phosphor gives emitted light that appears a specific color hue for example turquoise in color. The specific color hue, hereinafter referred to as the target color, is indicated as point 400 on the CIE chromaticity diagram of FIG. 5 and has chromaticity coordinates CIE (x₂, y₂).

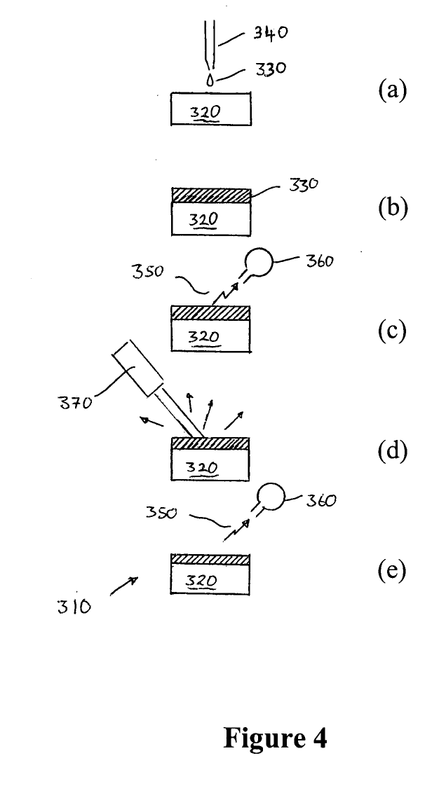

Referring to FIGS. 4(a) to (e) there are shown the method steps of the invention for fabricating a color light emitting device of a target color.

Step 1—FIGS. 4(a) and (b): The phosphor material is mixed with a transparent binder (bonding) material and a pre-selected quantity of the phosphor mixture 330 deposited on the light emitting surface of the LED chip 320. As with the first method the phosphor binder mixture can be deposited using a dispenser 340 such as nano-liter size plunger type dispenser head. However, unlike the first method, the pre-selected quantity of phosphor deposited is selected to ensure that the proportion of light generated by the phosphor is deliberately more than in the target color CIE (x₂, y₂), that is the device produces light having a higher proportion of green light.

Step 2—FIG. 4(c): The LED chip 320 is powered up and the color of light 350 emitted by the device measured using a photo-meter (calorimeter or spectrometer) 360. The measured color, indicated as point 420 in FIG. 5, is compared with the target color 400 and the amount of phosphor material to be removed to attain the target color is calculated. Referring to FIG. 5, the removal of phosphor material will move the color in the direction of the arrow 440 along a line 460. The line 460 connects points on the CIE diagram corresponding to the color of light emitted by the LED chip (blue in this example) and color of light emitted by the phosphor (green in this example). In a preferred apparatus, a LUT is used to determine the quantity of phosphor material to be removed. The LUT preferably includes the following parameters: target CIE (x₂, y₂), actual CIE (x,y), and quantity of phosphor to be removed.

Step 3—FIG. 4(d): The selected quantity of phosphor material is removed from the surface of the LED chip 320 to attain the target color. The phosphor material is preferably removed using a laser 370 to ablate the surface of the phosphor coating. Phosphor can alternatively be removed by other methods such as mechanical means including slicing; milling, abrading, drilling, routing, buffing, grinding or wiping before the binder material has set.

Step 4—FIG. 4(e): Optionally, the LED chip 320 is again powered up and the color of light emitted by the device 310 measured to verify that the device is emitting the target color CE (x₂, y₂) of light. As with the first method the measured color can be used to update the LUT and to refine the system or be used as a quality control check.

Since there can be a variation in the spectral emission of LED chips, the method can further comprise initially powering up the LED chip 320, measuring the color of its light emission using the photo-meter 360 and based on the measured color selecting the pre-selected quantity of phosphor mixture 330 to be deposited in step 1.

As with the first method, the method in accordance with the second embodiment can be used in the high volume production of light emitting devices and in the production of devices which comprise a plurality of LED chips. In the case of the latter, phosphor material can be selectively removed from one or more of the LED chips and the device can be optimized for net emitted light or each LED's light output color optimized.

A particular benefit of the methods of the invention is that they can eliminate the need for binning. The methods of the invention are intended for use with inorganic phosphor materials such as for example silicate-based phosphor of a general composition A₃Si(OD)₅ or A₂Si(OD)₄ in which Si is silicon, O is oxygen, A comprises strontium (Sr), barium (Ba), magnesium (Mg) or calcium (Ca) and D comprises chlorine (Cl), fluorine (F), nitrogen (N) or sulfur (S). Examples of silicate-based phosphors are disclosed in our co-pending patent applications US2006/0145123, US2006/028122, US2006/261309 and US2007029526 the content of each of which is hereby incorporated by way of reference thereto.

As taught in US2006/0145123, a europium (Eu²⁺) activated silicate-based green phosphor has the general formula (Sr,A₁)ₓ(Si,A₂)(O,A₃)₂₊ₓ:Eu²⁺ in which: A₁ is at least one of a 2+ cation, a combination of 1+ and 3+ cations such as for example Mg, Ca, Ba, zinc (Zn), sodium (Na), lithium (Li), bismuth (Bi), yttrium (Y) or cerium (Ce); A₂ is a 3+, 4+ or 5+ cation such as for example boron (B), aluminum (Al), gallium (Ga), carbon (C), germanium (Ge), N or phosphorus (P); and A₃ is a 1−, 2− or 3− anion such as for example F, Cl, bromine (Br), N or S. The formula is written to indicate that the A₁ cation replaces Sr; the A₂ cation replaces Si and the A₃ anion replaces O. The value of x is an integer or non-integer between 2.5 and 3.5.

US2006/028122 discloses a silicate-based yellow-green phosphor having a formula A₂SiO₄:Eu²⁺D, where A is at least one of a divalent metal comprising Sr, Ca, Ba, Mg, Zn or cadmium (Cd); and D is a dopant comprising F, Cl, Br, iodine (I), P, S and N. The dopant D can be present in the phosphor in an amount ranging from about 0.01 to 20 mole percent. The phosphor can comprise (Sr_{1-x-y}BaₓM_{y})SiO₄:Eu²⁺F in which M comprises Ca, Mg, Zn or Cd.

US2006/261309 teaches a two phase silicate-based phosphor having a first phase with a crystal structure substantially the same as that of (M1)₂SiO₄; and a second phase with a crystal structure substantially the same as that of (M2)₃SiO₅ in which M1 and M2 each comprise Sr, Ba, Mg, Ca or Zn. At least one phase is activated with divalent europium (Eu²⁺) and at least one of the phases contains a dopant D comprising F, Cl, Br, S or N. It is believed that at least some of the dopant atoms are located on oxygen atom lattice sites of the host silicate crystal.

US2007/029526 discloses a silicate-based orange phosphor having the formula (Sr₁₋ₓMₓ)_{y}Eu_{z}SiO₅ in which M is at least one of a divalent metal comprising Ba, Mg, Ca or Zn; 0<x<0.5; 2.6<y<3.3; and 0.001<z<0.5. The phosphor is configured to emit visible light having a peak emission wavelength greater than about 565 nm.

The phosphor can also comprise an aluminate-based material such as is taught in our co-pending patent applications US2006/0158090 and US2006/0027786 the content of each of which is hereby incorporated by way of reference thereto.

US2006/0158090 teaches an aluminate-based green phosphor of formula M₁₋ₓEuₓAl_{y}O_{[1+3y/2]} in which M is at least one of a divalent metal comprising Ba, Sr, Ca, Mg, Mn, Zn, Cu, Cd, Sm and thulium (Tm) and in which 0.1<x<0.9 and 0.5≦y≦12.

US2006/0027786 discloses an aluminate-based phosphor having the formula (M₁₋ₓEuₓ)_{2-z}Mg_{z}Al_{y}O_{[1+3y/2]} in which M is at least one of a divalent metal of Ba or Sr. In one composition the phosphor is configured to absorb radiation in a wavelength ranging from about 280 nm to 420 nm, and to emit visible light having a wavelength ranging from about 420 nm to 560 rm and 0.05<x<0.5 or 0.2<x<0.5; 3≦y≦12 and 0.8≦z≦1.2. The phosphor can be further doped with a halogen dopant H such as Cl, Br or I and be of general composition (M₁₋ₓEuₓ)_{2-z}Mg_{z}Al_{y}O_{[1+3y/2]}:H.

It will be appreciated that the phosphor is not limited to the examples described herein and can comprise any inorganic phosphor material including for example nitride and sulfate phosphor materials, oxy-nitrides and oxy-sulfate phosphors or garnet materials (YAG).

It will be further appreciated that the present invention is not restricted to the specific embodiments described and that variations can be made that are within the scope of the invention. For example, in other embodiments of the invention different light emitting phosphor materials can be used to tune (tune) the device to a target color hue or CCT. In one embodiment a warm white (WW) light emitting device having a target CCT (for example 3000K) can be fabricated by firstly depositing a pre-selected quantity of a first phosphor, for example a yellow light emitting phosphor, on a blue LED chip to produce a light emitting device that emits cold white (CW) light having for example a CCT of 6000-7000K. The device is then powered up and the color of its light emission measured and compared with the target color (CCT). In response to the comparison a selected quantity of a second phosphor, such as a green light emitting phosphor, is then deposited on the device to tune (trim) the emission CCT to the target CCT. Moreover, Whilst the first method has been described in relation to the fabrication of a white light emitting device, it will be appreciated that the method can be used to fabricate light emitting devices of any color and/or of a particular color hue.

The phosphor material(s) can be deposited using any technique such as for example ink jet printing, spraying etc. It is also envisaged to deposit the phosphor material as a pattern comprising for example an array of equally spaced non-overlapping areas (dots) of varying size using a halftone system. When using two different phosphor materials the dots alternate between phosphor materials and the relative size and/or spacing of the dots is used to control the relative quantities of the two phosphors.

The phosphor can be mixed with other binder materials and in one embodiment it is envisaged to use a UV curable material such as a UV curable silicone material. Here, this UV cure method is advantageous especially where high through-put systems are desired as is most often the case.

Moreover, the method can comprise a combination of the methods of the invention that is selectively adding and/or removing phosphor material to attain a specific target color hue.

What is claimed is:

1. A method of fabricating a light emitting device having a specific target color of emitted light, the device comprising at least one light emitting diode operable to emit light of a first wavelength range and at least one phosphor material which converts at least a part of the light into light of a second wavelength range wherein light emitted by the device comprises the combined light of the first and second wavelength ranges, the method comprising:
a) depositing a pre-selected quantity of the at least one phosphor material on a light emitting surface of the at least one light emitting diode;
b) operating the at least one light emitting diode;
c) measuring the color of light emitted by the device;
d) comparing the measured color with the specific target color; and
e) in dependence on the comparison depositing and/or removing a quantity of a phosphor material substantially to attain the specific target color.

2. The method according to claim 1, and comprising selecting the pre-selected quantity to ensure that the proportion of light of the second wavelength range is lower than is required in the specific target color.

3. The method according to claim 1, and comprising selecting the pre-selected quantity to ensure that the proportion of light of the second wavelength range is greater than in the specific target color.

4. The method according to claim 1, and comprising selecting the quantity of phosphor material to be deposited and/or removed using a look-up table.

5. The method according to claim 1, and further comprising operating the at least one light emitting diode a further time and measuring the color of light emitted by the device.

6. The method according to claim 4, and further comprising operating the at least one light emitting diode a further time; measuring the color of light emitted by the device and updating the look-up table.

7. The method according to claim 1, and comprising removing the phosphor material using a method selected the group consisting of: ablating; slicing; milling; abrading; drilling; routing; buffing and grinding.

8. The method according to claim 1, wherein when the light emitting device comprises a plurality of light emitting diodes including at least one phosphor material, the method comprising:
a) depositing a pre-selected quantity of the at least one phosphor material on a light emitting surface of each light emitting diode;
b) operating simultaneously each of the light emitting diodes;
c) measuring the color of light emitted by the device;
d) comparing the measured color with the specific target color; and
e) in dependence on the comparison depositing on, and/or removing from, a selected number of the light emitting diodes a fixed quantity of a phosphor material, the number being selected to substantially to attain the specific target color.

9. A method of fabricating a light emitting device having a specific target color of emitted light, the device comprising at least one light emitting diode operable to emit light of a first wavelength range and at least first and second phosphor materials which respectively convert at least a part of the light into light of second and third wavelength ranges wherein light emitted by the device comprises the combined light of the first, second and third wavelength ranges, the method comprising:
a) depositing pre-selected quantities of the first and second phosphor materials on a light emitting surface of the at least one light emitting diode;
b) operating the at least one light emitting diode;
c) measuring the color of light emitted by the device;
d) comparing the measured color with the specific target color; and
e) in dependence on the comparison depositing and/or removing selected quantities of the first and second phosphor materials substantially to attain the specific target color.

10. The method according to claim 9, and comprising selecting the pre-selected quantities to ensure that the proportion of light of the second and third wavelength ranges are lower than in the specific target color.

11. The method according to claim 9, and comprising selecting the pre-selected quantities to ensure that the proportion of light of the second and third wavelength ranges are greater than in the specific target color.

12. The method according to claim 9, and comprising selecting the quantities of phosphor materials to be deposited and/or removed using a look-up table.

13. The method according to claim 9, and further comprising operating the light emitting diode a further time and measuring the color of light emitted by the device.

14. The method according to claim 12, and further comprising operating the at least one light emitting diode a further time; measuring the color of light emitted by the device and updating the look-up table.

15. The method according to claim 9, wherein when the light emitting device comprises a plurality of light emitting diodes including at least first and second phosphor materials, the method comprising in dependence on the comparison depositing on, and/or removing from, a selected number of the light emitting diodes fixed quantities of the phosphor materials, the number being selected to substantially to attain the specific target color.

16. Apparatus for fabricating a light emitting device having a specific target color of emitted light, the device comprising at least one light emitting diode operable to emit light of a first wavelength range and at least one phosphor material which converts at least a part of the light into light of a second wavelength range wherein light emitted by the device comprises the combined light of the first and second wavelength ranges, the apparatus comprising:
a dispenser for depositing a pre-selected quantity of the at least one phosphor material on a light emitting surface of the at least one light emitting diode;
a controller operable to operate the at least one light emitting diode;
light measuring means for measuring the color of light emitted by the device;
wherein the controller is operable to compare the measured color with the specific target color and in dependence on the comparison to deposit a further selected quantity of a phosphor material substantially to attain the specific target color.

17. The apparatus according to claim 16, and comprising selecting the pre-selected quantity to ensure that the proportion of light of the second wavelength range is lower than in the specific target color.

18. The apparatus according to claim 16, and further comprising a look-up table for selecting the quantity of further phosphor material to be deposited.

19. The apparatus according to claim 18, and further comprising operating the at least one light emitting diode a further time; measuring the color of light emitted by the device and updating the look-up table.

20. The apparatus according to claim 16, wherein the dispenser comprises a plunger type dispenser head.

21. The apparatus according to claim 16, wherein when the light emitting device comprises a plurality of light emitting diodes including at least one phosphor material, the controller is operable in dependence on the comparison to deposit on a selected number the light emitting diodes a fixed quantity of the phosphor material, the number being selected to substantially to attain the specific target color.

22. Apparatus for fabricating a light emitting device having a specific target color of emitted light, the device comprising at least one light emitting diode operable to emit light of a first wavelength range and at least one phosphor material which converts at least a part of the light into light of a second wavelength range wherein light emitted by the device comprises the combined light of the first and second wavelength ranges, the apparatus comprising:
a dispenser operable to deposit a pre-selected quantity of the at least one phosphor material on a light emitting surface of the at least one light emitting diode;
a controller operable to operate the at least one light emitting diode;
light measuring means for measuring the color of light emitted by the device; and
phosphor removing means operable to remove a quantity of phosphor material to attain the specific target color, wherein the controller is operable to compare the measured color with the specific target color and in dependence on the comparison to select the quantity of phosphor material to be removed substantially to attain the specific target color.

23. The apparatus according to claim 22, and comprising selecting the pre-selected quantity to ensure that the proportion of light of the second wavelength range is greater than in the specific target color.

24. The apparatus according to claim 22, and further comprising a look-up table for selecting the quantity of phosphor material to be removed.

25. The apparatus according to claim 24, and further comprising operating the at least one light emitting diode a further time; measuring the color of light emitted by the device and updating the look-up table.

26. The apparatus according to claim 22, wherein the phosphor removing means comprises a laser operable to ablate the selected quantity of phosphor material.

27. The apparatus according to claim 22, wherein when the light emitting device comprises a plurality of light emitting diodes including at least one phosphor material, the controller is operable in dependence on the comparison to remove from a selected number the light emitting diodes a fixed quantity of the phosphor material, the number being selected to substantially to attain the specific target color.

28. Apparatus for fabricating a light emitting device having a specific target color of emitted light, the device comprising at least one light emitting diode operable to emit light of a first wavelength range and first and second phosphor materials which respectively convert at least a part of the light into light of second and third wavelength ranges wherein light emitted by the device comprises the combined light of the first, second and third wavelength ranges, the apparatus comprising:
a first dispenser for depositing a pre-selected quantity of a mixture of the first and second phosphor materials on a light emitting surface of the at least one light emitting diode;
a second dispenser for depositing the first phosphor material;
a third dispenser for depositing the second;
a controller operable to operate the at least one light emitting diode;
light measuring means for measuring the color of light emitted by the device;
wherein the controller is operable to compare the measured color with the specific target color and in dependence on the comparison to deposit using the second and third dispensers selected quantities of the first and second phosphor materials substantially to attain the specific target color.
